(19) United States
(12) Patent Application Publication
(10) Pub. No.: US 2003/0040162 A1
(43) Pub. Date: Feb. 27, 2003

(54) Method for fabricating a capacitor

(75) Inventors: Ho-Jin Cho, Kyoungki-Do (KR); Hyung-Bok Choi, Kyoungki-do (KR)

Correspondence Address: MARSHALL, GERSTEIN & BORUN, 6300 SEARS TOWER, 233 SOUTH WACKER, CHICAGO, IL, 60606-6357, US

(73) Assignee: HYNIX SEMICONDUCTOR INC., Ichon-shi (KR)

(21) Appl. No.: 10/223,280

(22) Filed: Aug. 19, 2002

(30) Foreign Application Priority Data
Aug. 24, 2001 (KR) 2001-51399

(51) Int. Cl. H01L 21/20; H01L 21/8242

(52) U.S. Cl. 438/396; 438/253

(57) ABSTRACT

Disclosed is a method for fabricating a capacitor, comprising the steps of forming a bottom electrode on the semiconductor substrate by an electro chemical deposition (ECD) technique, performing a wet-cleaning process for removing impurities of a surface of the bottom electrode, forming a dielectric layer on the bottom electrode and forming a top electrode on the dielectric layer.

### TECHNICAL FIELD

A method for fabricating a capacitor is disclosed, and more particularly, a method for fabricating a capacitor capable for reducing a current leakage is disclosed.

### BACKGROUND

A capacitance of a capacitor in a semiconductor device is represented as ∈A/d, where ‘∈’ represents a dielectric constant, ‘A’ represents a surface area and ‘d’ represents a thickness of a dielectric layer. That is, the capacitance is proportioned to a surface area of a storage electrode and a dielectric constant of a dielectric material.

As a semiconductor device is highly integrated, in order to obtain a desired capacitance for a reliable operation thereof, the storage electrode is formed into a three-dimensional (3-D) structure to increase the surface area and high dielectric materials, such as BaTiO₃, SrTiO₃ or the like, has been used in the fabrication of the electrode. However, a complicated process is required to form the storage electrode into the 3-D structure so that fabrication costs increase and process efficiency decreases. Also, when high dielectric materials are used, it is difficult to maintain the oxygen stoichiometry. As a result, current leakage increases.

Also, when the high dielectric materials are used in the capacitor, noble metals, such as Pt, Ru or the like, which have a high oxygen resistance, must be used. Because noble metals are very stable against an etching process and are etched by a dry etching technique, such as a sputtering technique or the like, there is a problem in that it is difficult to obtain a desired vertical profile of the storage electrode layer.

To solve the above problems, research has been conducted where, after forming a capacitor pattern by using a sacrifice layer, such as an oxide layer or the like, the noble metal is deposited by an electro chemical deposition (ECD) technique and an etch back process follows.

FIGS. 1A to 1C are cross-sectional views illustrating a conventional process for fabricating a capacitor. Referring to FIG. 1A, a wordline (not shown) and a source/drain 12 are formed on a semiconductor substrate 11 and an interlayer insulating layer 13 is formed on the semiconductor substrate 11. The interlayer insulating layer 13 is selectively etched to form a contact hole exposing a predetermined portion of the source/drain 12 and a polysilicon is deposited on the entire structure. A polysilicon plug 14, which is buried in the contact hole, is formed by using an etchback process or a chemical mechanical polishing (CMP) process.

A Pt seed layer 15 is formed on the polysilicon plug 14 and a sacrifice layer 16 is formed on the Pt seed layer 15. The Pt seed layer 15 is formed with a physical vapor deposition (PVD) technique to form a bottom electrode by using an electro chemical deposition (ECD) technique.

Subsequently, a mask 17 for a storage node is formed by patterning the capacitor sacrifice layer 16 by using a photolithography process. The capacitor sacrifice layer 16 is dry-etched by using CF₄ gas, CHF₃ gas or C₂F₆ gas so that an opening 18 exposing a surface of the Pt seed layer 15 is formed.

Referring to FIG. 1B, when bias voltage is applied to the Pt seed layer 15, Pt is deposited on the exposed Pt seed layer 15 with an electro chemical deposition technique to form a bottom electrode 19 and the remaining sacrifice layer 16 is etched to expose the Pt seed layer 15, on which the Pt for the electrode 19 has not been deposited. Also, the exposed Pt seed layer 15 is removed through the etch back process. At this time, since the Pt seed layer 15 is separated into several parts, the bottom electrode is isolated from neighboring cells.

When the bottom electrode 19 is formed, an alkaline family or a base family is used as the electrolyte and addictives, such as a ligand of a polymer family or an OH family, are added into the electrolyte to improve a gap-fill characteristic of a fine pattern and a selective deposition characteristic.

Impurities, which the addictives are decomposed by an electric field between an anode and a cathode in ECD process, remain in the surface of the bottom electrode 19. That is, since the bonds between chains in the polymer are broken and the broken polymer is inserted into the bottom electrode 19, the impurities ‘A’ remain on the surface on the bottom electrode 19.

Referring to FIG. 1C, a BST layer 20 is deposited on the entire structure including the bottom electrode 19 by using a chemical vapor deposition (CVD) technique. A top electrode is formed on the BST layer 20.

However, when the capacitor is fabricated such an above process, a defect ‘B’, such as a trap or the like, is generated so that a current leakage characteristic is deteriorated and a hump occurs as shown in a current-voltage curve of FIG. 4A. Also, breakdown voltage of the BST dielectric layer 20 decreases.

After removing the seed layer 15 to separate each cell, a cleaning process can be additionally performed by using an etching solution of a standard cleaning (SC) family. At this time, the cleaning process is to remove etching residues generated in the etch back process, however, it is not easy to remove these impurities through the general cleaning process.

### SUMMARY OF THE DISCLOSURE

A method for fabricating a capacitor is disclosed which improves the electrical characteristics thereof by reducing defects between the bottom electrode and the dielectric layer.

One disclosed method comprises: a) forming a bottom electrode on the semiconductor substrate by an electro chemical deposition (ECD) technique; b) performing a wet-cleaning process for removing impurities of a surface of the bottom electrode; c) forming a dielectric layer on the bottom electrode; and d) forming a top electrode on the dielectric layer.

Another disclosed method comprises: a) forming a seed layer on a semiconductor substrate; b) forming a capacitor sacrifice layer on the seed layer; c) exposing a portion of the seed layer by selectively etching the capacitor sacrifice layer; d) forming a bottom electrode on the exposed seed layer by using an electro chemical deposition (ECD) technique; e) removing the sacrifice layer; f) performing an etch back process to isolate the bottom electrode; g) performing wet-cleaning for removing impurities on the surface of the bottom electrode and remainders after etching of the seed layer; h) forming a dielectric layer on the bottom electrode; and i) forming a top electrode on the dielectric layer.

### BRIEF DESCRIPTION OF THE DRAWINGS

The above and other features of the disclosed method will become apparent from the following description of preferred embodiments taken in conjunction with the accompanying drawings, wherein:

FIGS. 1A to 1C are cross-sectional views illustrating a process for fabricating a conventional capacitor;

FIGS. 2A to 2D are cross-sectional views illustrating a process for fabricating a capacitor in accordance with a first embodiment of the disclosure;

FIGS. 3A to 3D are cross-sectional views illustrating a process for fabricating a capacitor in accordance with a second embodiment of the disclosure; and

FIG. 4A illustrates graphically, a current-voltage characteristic of a conventional capacitor; and

FIG. 4B a current-voltage characteristic of a capacitor in accordance with the disclosed methods.

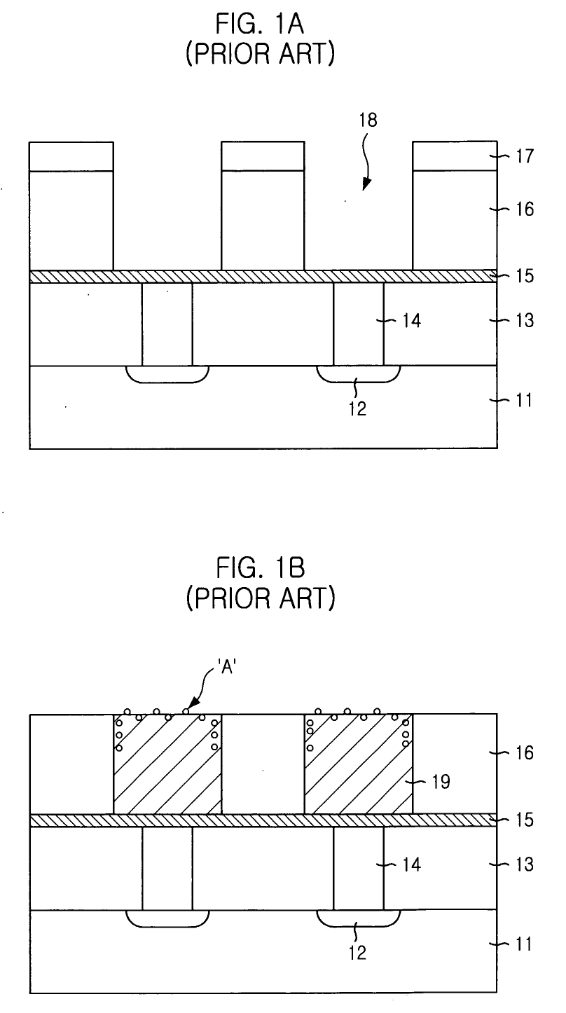

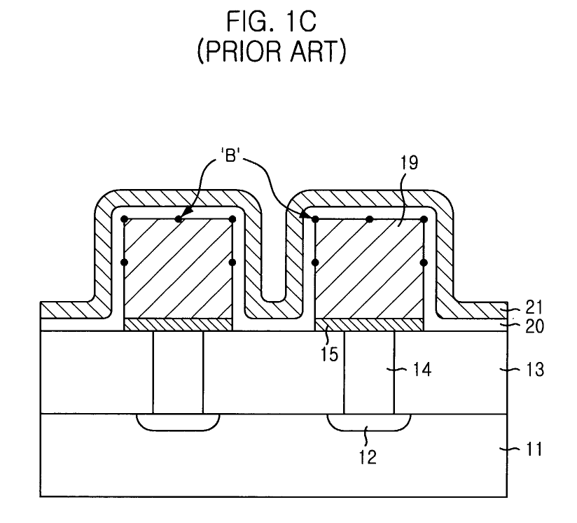

### DETAILED DESCRIPTION OF THE PRESENTLY PREFERRED EMBODIMENTS

Hereinafter, the disclosed methods for fabricating capacitors in semiconductor devices will be described in detail referring to the accompanying drawings.

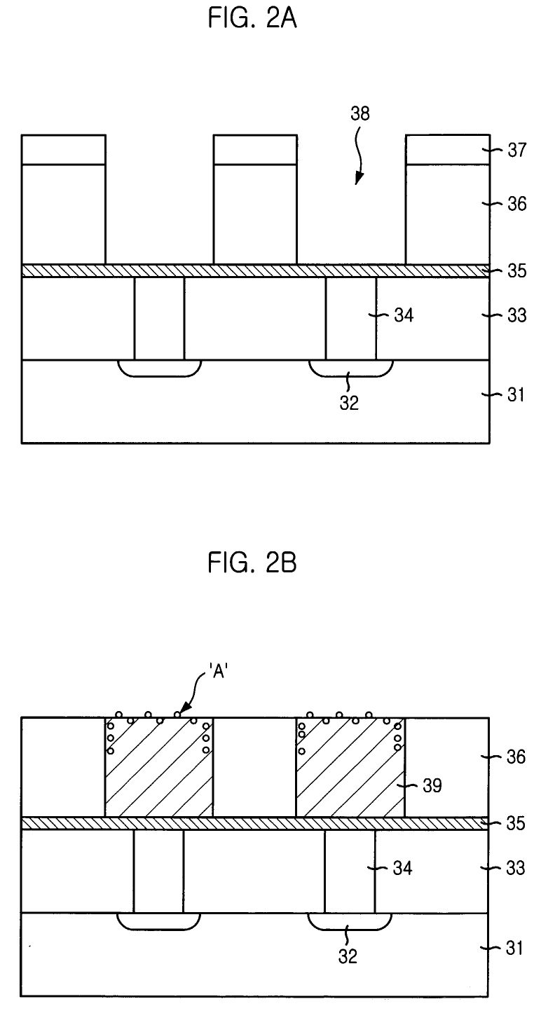

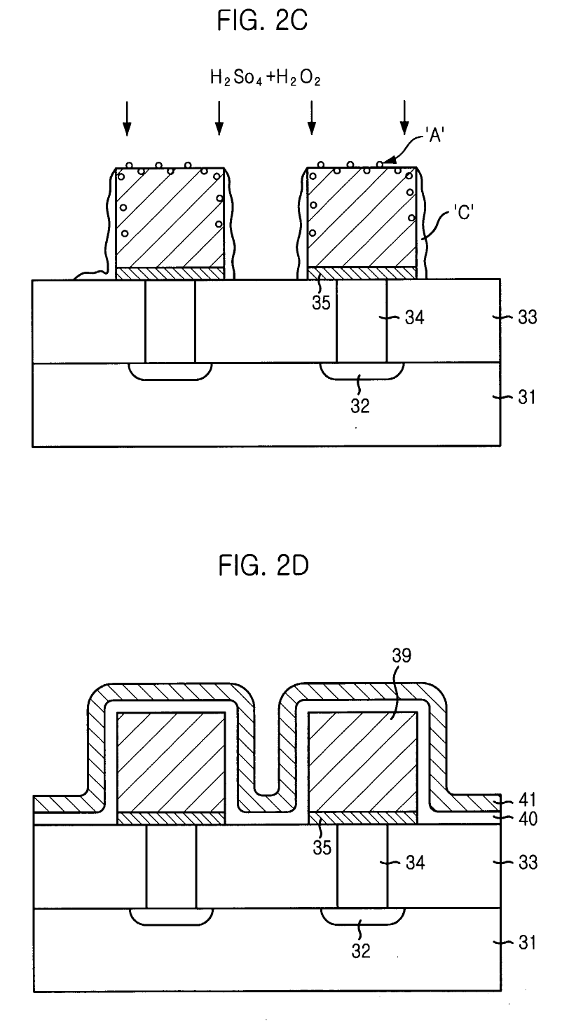

FIGS. 2A to 2D are cross-sectional views illustrating a fabricating capacitor according to one disclosed method.

Referring to FIG. 2A, an interlayer insulating layer 33 is formed on a semiconductor substrate 31 including a wordline (not shown) and a source/drain 32. The interlayer insulating layer 33 is formed with a material selected from a group consisting of phospho silicate glass (PSG), boro phospho silicate glass (BPSG), high density plasma (HDP) oxide, undoped silicate glass (USG), tetra ethyl ortho silicate (TEOS), advanced planarization layer (APL) oxide, spin on glass (SOG), flowfill and combinations thereof.

When considering a loss and an etching selection ratio of the interlayer insulating layer 33, a layer of a nitride layer family can be formed thereon by the CVD technique at a thickness ranging from about 300 Å to about 1000 Å. A contact hole (not shown), which exposes the predetermined portion of the source/drain 32 by selectively etching the interlayer insulating layer 33, is formed. A conductive material is buried in the contact hole and a planarization process is performed until the conductive material remains only in the contact hole so that a conductive plug 34 is formed.

More concretely, a conductive material such as a polysilicon is deposited on the entire structure including a contact hole to be sufficiently buried and the CMP process or an etch back process is performed in order that the plug 34 remains only in the contact hole. At this time, the polysilicon doped with phosphorus may be used. Also, the conductive material is used with a material selected from a group consisting of tungsten (W), tungsten nitride (WN), TiN, TiAlN, TaSiN, TiSiN, TaN, TaAlN, TiSi and TaSi. The plug material is deposited by a CVD technique, a PVD technique or an ALD technique.

Subsequently, a Ti layer is deposited and an etching process using a mask is performed in order that the Ti layer remains only on the polysilicon plug 34 and then a thermal treatment process is carried out to react the polysilicon plug 33 and Ti so that titanium silicide layer (not shown) is formed on the polysilicon plug 33. The titanium silicide layer is to form Ohmic's contact between the polysilicon plug 33 and a bottom electrode to be formed. The process for forming the titanium silicide can be omitted and a metal silicide such as WSiₓ, MoSiₓ, CoSiₓ, NoSiₓ or TaSiₓ can be used instead of the titanium silicide. A recess plug can be formed in the contact hole. At this time, a depth of the recess ranging from about 500 Å to about 1500 Å is preferable when considering a thickness of the interlayer insulating layer 33.

Also, a barrier layer including a barrier metal layer and an oxygen diffusion barrier layer can be formed on the titanium silicide. The barrier metal layer is formed with a material selected from a group consisting of TiN, TiAlN, TaSiN, TiSiN, TaN, RuTiN and RuTiO and the oxygen diffusion barrier layer is formed with a material selected from a group consisting of Ir, Ru, Pt, Re, Ni, Co and Mo.

The oxygen diffuision barrier is to protect an oxygen diffusion when a thermal treatment for crystallization of a high constant dielectric material or a ferroelectric material is carried out. It is preferable to additionally perform a N₂ or O₂ plasma treatment to improve a diffusion barrier characteristic. Also, a thermal treatment process can be performed at the same time.

A seed layer 35 is formed with a material selected from a group consisting of Pt, Ru, Ir, Os, W, Mo, Co, Ni, Au, and Ag by a PVD technique at a thickness ranging from about 50 Å to about 1000 Å.

Subsequently, a capacitor sacrifice layer 36 is relatively and thickly formed at a thickness ranging from about 5000 Å to about 10000 Å and then a mask 37 for a storage node is formed by using a photolithography. An opening, which exposes a portion of the seed layer by a dry etching process using a CF₄ gas, a CHF₃ gas or a C₂F₆ gas, is opened and then a cleaning process is carried out. A non-conductive material, such as general oxide family, a sensitive film or the like, is used as the capacitor sacrifice layer 36.

Referring to FIG. 2B, a bottom electrode 39 is formed on the seed layer 35 by using an electro chemical deposition technique and the mask 37 is removed through a PR strip process. When the bottom electrode 39 is formed with the ECD technique, a current, such as a DC, a pulse current or a pulse reverse current, is used and a current density is 0.1 mA/cm² to 10 mA/cm² so that a vertical step coverage of the bottom electrode 39 is adjusted with the capacitor sacrifice layer 36.

When forming the bottom electrode 39, a alkali family or a base family is used as a electrolyte and addictives, such as a ligand of a polymer family or an OH family, are added into the electrolyte to improve a gap-fill characteristic of a fine pattern and a selective deposition characteristic.

Impurities, which the addictives are decomposed by an electric field between anode and cathode in ECD process, remain in the surface of the bottom electrode 39. That is, since the bonds between chains in the polymer are broken and the broken polymer is inserted into the bottom electrode 39, the impurities ‘A’ remain on the surface on the bottom electrode 39. Accordingly, the impurities include the polymer family or an OH family, which is in the electrolyte for the ECD.

Referring to 2C, the capacitor sacrifice layer 36 is etched until the surface of the seed layer 33 is exposed and, subsequently, the etch back process is performed to remove the seed layer 33 of the portion, which the bottom electrode 39 is not deposited so that the bottom electrode 39 is separated from the adjacent cells.

The etching process of the capacitor sacrifice 36 is carried out with a wet etch using a HF solution or a mixed solution of HF and NH₄F and the seed layer 35 is generally removed by a dry etch.

When the seed layer 35 is removed by the dry etch, impurities, such as Pt or the like, are deposited again at the lateral side of the bottom electrode 39 so that the impurities remain as a remainder ‘C’. Accordingly, the remainder ‘C’ and the impurities ‘A’ deteriorating a current leakage characteristic has to be removed. Generally, in a cleaning process using a solution of a SC family, such as SC or the like, the remainder ‘C’ may be removed, but a removal of the impurities ‘A’ is not easy.

Accordingly, the following solutions will be used to remove the remainder ‘C’ and the impurities ‘A’ at the same time according to the present invention. Namely, a first solution including H₂SO₄ and H₂O₂, a second solution adding NH₄OH in the first solution or a third solution including NH₄OH and H₂O is used.

When the first solution is used, it is preferable that the volume ratio of H₂SO₄ and H₂O₂ of about 100 to 1 and a temperature ranging from about 25° C. to about 150° C. When the third solution is used, it is preferable that the volume ratio of NH₄OH and H₂O is about 500 to 1 and a temperature ranging from about 25° C. to about 150° C. Also, the cleaning process is carried out for a time period ranging from about 10 seconds to about 3600 seconds so that the remainder ‘C’ and the impurities ‘A’ can be removed at the same time.

Referring to FIG. 2D, a dielectric layer 40 and a top electrode 41 are formed in this order on the bottom electrode 39. The dielectric layer 40 is formed with a material selected from a group consisting of TiO₂, HFO₂, Y₂O₃, STO (SrTiO₃), BST, PZT, PLZT ((Pb, La)(ZR, Ti)O₃), BTO (BaTiO₃), PMN (Pb(Ng_{⅓}Nb_{⅔})O₃), SBTN ((Sr, Bi)(Ta, Nb)₂O₉), SBT ((Sr, Bi)Ta₂O₉), BLT ((Bi, La)Ti₃O₁₂), BT (BaTiO₃), ST (SrTiO₃) and PT (PbTiO₃) by a technique of spin-on, CVD, ALD, PVD or the like at a thickness of 150 Å to 500 Å. When the CVD technique is used for depositing BST, a deposition temperature ranging from about 300° C. to about 500° C. is used.

A thermal treatment process for crystallization of the dielectric layer 40 to improve the dielectric constant is performed at an ambient of O₂, N₂, Ar, O₃, He, Ne or Kr gas and at a temperature ranging from about 400° C. to about 800° C. The crystallization of the dielectric layer 40 can be carried out with the diffusion chamber thermal treatment process or the rapid thermal process for a time period ranging from about 30 seconds to about 180 seconds.

A top electrode 41 is formed on the dielectric layer 40 and a predetermined patterning process and a metal wiring process are followed so that a process for forming the capacitor is completed. The top electrode 41 may be formed with a material identical to the bottom electrode 39 by using a technique of CVD or PVD instead of the ECD technique.

As the cleaning process is performed just after forming the bottom electrode 39, that is, before forming the dielectric layer 40, the by-products generated from the etching process of the seed layer 35 and the impurities inserted into the bottom electrode 39 when performing the electro chemical deposition process can be removed so that the generation of defects, such as trap or the like, which are generated at the boundary of the bottom electrode 39 and the dielectric layer 40, can be basically suppressed.

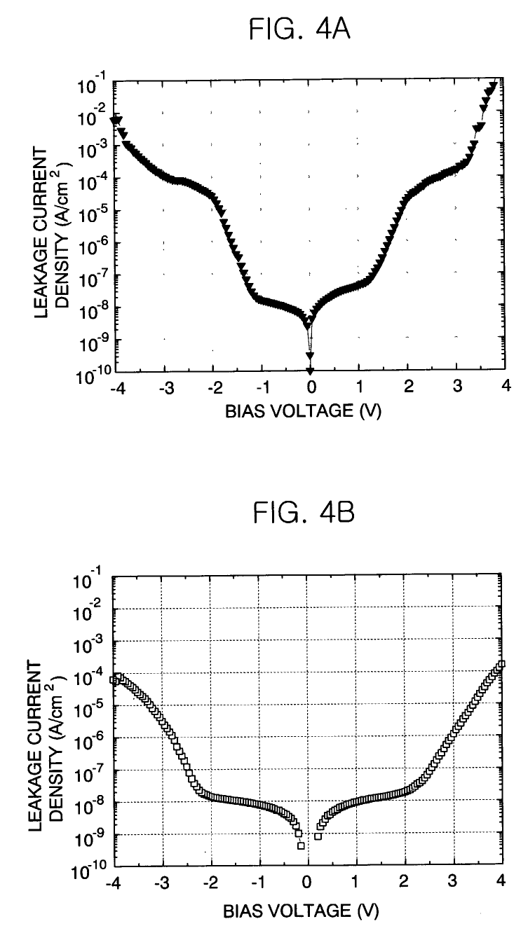

FIG. 4B is a graphic diagram showing a current-voltage characteristic of the capacitor in accordance with the present invention, where the horizontal axis represents bias voltage (V) and the vertical axis represents current leakage (A/cm²).

Referring to FIG. 4B, in the current-voltage characteristic according to the present invention, the trap, such as a hump or the like, is not shown and a low current leakage value is shown. Also, a transition voltage, which the current leakage suddenly increases, is high. The high transition voltage shows that a Shottky barrier of a boundary of the bottom electrode 39 and the dielectric layer 40 is high, that is, shows that the trap is not existed in the boundary.

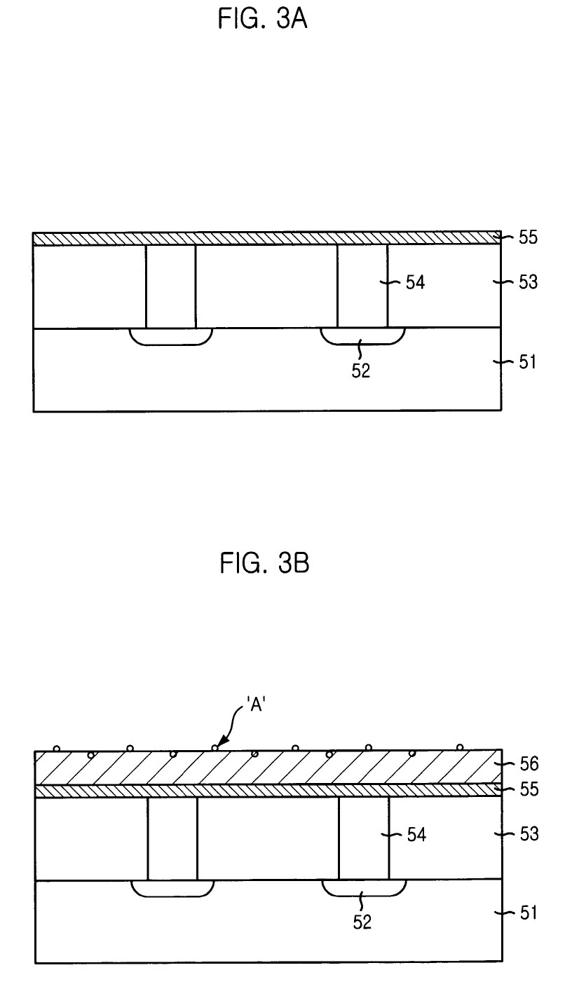

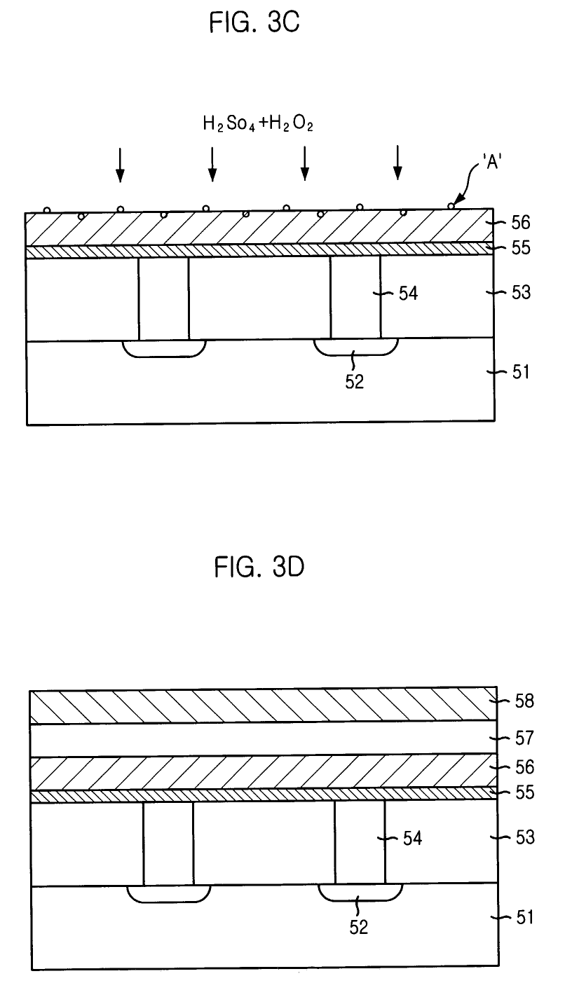

FIGS. 3A to 3D are cross-sectional views showing a fabricating process of a capacitor in accordance with another present invention. The difference for the aforementioned embodiment of the present invention is that a separation of the bottom electrode from adjacent bottom electrode is carried out in the post process.

Referring to FIG. 3A, a seed layer 55 is formed on a lower structure including a plug 55. The number reference ‘51’, ‘52’, ‘53’, not mentioned in the above, represent a semiconductor substrate, a source/drain and an interlayer insulating layer, respectively. Referring to FIG. 3B, when the bottom electrode 56 is formed with the ECD technique on the seed layer 55, a current, such as a DC, a pulse current or a pulse reverse current, is used and a current density ranging from about 0.1 mA/cm² to about 10 mA/cm².

When forming the bottom electrode 56, a alkali family or a base family is used as a electrolyte and addictives, such as a ligand of a polymer family or an OH family, are added into the electrolyte to improve a gap-fill characteristic of a fine pattern and a selective deposition characteristic.

Impurities, which the addictives are decomposed by an electric field between anode and cathode in ECD process, remain in the surface of the bottom electrode 56. That is, since the bonds between chains in the polymer are broken and the broken polymer is inserted into the bottom electrode 56, the impurities ‘A’ remain on the surface on the bottom electrode 56. Accordingly, the impurities include the polymer family or an OH family, which is in the electrolyte for the ECD.

Referring to FIG. 3C, the following solutions will be used to remove impurities ‘A’ in accordance with the present invention. Namely, a first solution including H₂SO₄ and H₂O₂, a second solution adding NH₄OH in the first solution or a third solution including NH₄OH and H₂O is used.

When the first solution is used, it is preferable that the volume ratio of H₂SO₄ and H₂O₂ is about 100 to 1 and at a temperature ranging from about 25° C. to about 150° C. When the third solution is used, it is preferable that the volume ratio of NH₄OH and H₂O is about 500:1 and at a temperature ranging from about 25° C. to about 150° C. Also, the cleaning process is carried out for a time period ranging from about 10 seconds to about 3600 seconds so that the impurities ‘A’ can be removed.

Referring to FIG. 3D, a dielectric layer 57 and a top electrode 58 are formed in this order on the bottom electrode 56.

There are three etching processes to form a pattern of a capacitor. A first etching process is to form a pattern of the bottom electrode 56 and a second etching process is to form a pattern of the dielectric layer 57. The last etching process is to form a pattern of the top electrode 58. The etching processes can be performed at once. Also, the etching processes are separated with two steps, that is, the etching processes can be variously performed.

When the bottom electrode is formed by using the ECD technique, impurities, such as a polymer or the like, included in an electrolyte, remain in a bottom electrode. As the cleaning process is performed in accordance with the present invention, the impurities and by-products generated from the etching process of the seed layer can be removed so that defects of a boundary between the bottom electrode and dielectric layer can be basically suppressed and a current leakage characteristic is improved.

The present invention can be applied not only to the capacitor using the ECD electrode and the sacrifice layer, but also to all of semiconductor devices using the ECD electrode.

While the present invention has been described with respect to the particular embodiments, it will be apparent to those skilled in the art that various changes and modifications may be made without departing from the spirit and scope of the invention as defined in the following claims.

What is claimed is:

1. A method for fabricating a capacitor comprising:
a) forming a bottom electrode on the semiconductor substrate by an electro chemical deposition (ECD) technique;
b) performing a wet-cleaning process for removing impurities on a surface of the bottom electrode;
c) forming a dielectric layer on the bottom electrode; and
d) forming a top electrode on the dielectric layer.

2. The method as recited in claim 1, wherein the impurities comprise a polymer or an alcohol included in an electrolyte for the ECD.

3. The method as recited in claim 1, wherein part b) is performed by using a first solution comprising H₂SO₄ and H₂O₂.

4. The method as recited in claim 3, wherein a volume ratio of H₂SO₄ to H₂O₂ in the first solution is about 100:1 and a temperature of the first solution ranges from about 25° C. to about 150° C.

5. The method as recited in claim 3, wherein the first solution further comprises NH₄OH.

6. The method as recited in claim 1, wherein the part b) is performed by using a second solution comprising NH₄OH and H₂O.

7. The method as recited in claim 6, wherein a volume ratio of NH₄OH to H₂O in the second solution is about 500:1 and a temperature of the second solution ranges from about 25° C. to about 150° C.

8. The method as recited in claim 3, wherein part b) is performed for a time period ranging from about 10 seconds to about 3600 seconds.

9. The method as recited in claim 1, wherein part a) comprises:
a1) forming a seed layer on the semiconductor substrate; and
a2) forming a bottom electrode on the seed layer by the ECD technique.

10. The method as recited in claim 9, wherein the seed layer is formed at a thickness ranging from about 50 Å to about 1000 Å by a physical vapor deposition (PVD) technique.

11. The method as recited in claim 1, wherein part a) is performed at a current density ranging from about 0.1 mA/cm² to about 10 mA/cm².

12. The method as recited in claim 1, wherein part a) is performed by using a direct current (DC), a pulse current or a pulse inverse current.

13. The method as recited in claim 1, where the bottom electrode is formed from a material selected from a group consisting of Pt, Ru, Ir, Os, W, Mo, Co, Ni, Au and Ag.

14. A method for fabricating a capacitor, comprising:
a) forming a seed layer on a semiconductor substrate;
b) forming a capacitor sacrifice layer on the seed layer;
c) exposing a portion of the seed layer by selectively etching the capacitor sacrifice layer;
d) forming a bottom electrode on the exposed portion of the seed layer by using an electro chemical deposition (ECD) technique;
e) removing the capacitor sacrifice layer;
f) performing an etch back process to isolate the bottom electrode;
g) performing wet-cleaning for removing impurities on the surface of the bottom electrode after etching of the seed layer;
h) forming a dielectric layer on the bottom electrode; and
i) forming a top electrode on the dielectric layer.

15. The method as recited in claim 14, wherein the impurities comprise polymer or an alcohol OH included in an electrolyte for the ECD.

16. The method as recited in claim 14, wherein part f) is performed by using a first solution comprising H₂SO₄ and H₂O₂.

17. The method as recited in claim 16, wherein a volume ratio of H₂SO₄ to H₂O₂ in the first solution is about 100:1 and a temperature of the first solution ranges from about 25° C. to about 150° C.

18. The method as recited in claim 16, wherein the first solution comprises NH₄OH.

19. The method as recited in claim 14, wherein part f) is performed by using a second solution comprising NH₄OH and H₂O.

20. The method as recited in claim 19, wherein a volume ratio of NH₄OH to H₂O in the second solution is about 500:1 and a temperature of the second solution ranges from about 25° C. to about 150° C.

21. The method as recited in claim 16, wherein the part f) is performed for a time period ranging from about 10 seconds to about 3600 seconds.

22. The method as recited in claim 14, wherein the bottom electrode is formed from a material selected from a group consisting of Pt, Ru, Ir, Os, W, Mo, Co, Ni, Au and Ag.

23. A capacitor made in accordance with the method of claim 1.

24. A capacitor made in accordance with the method of claim 14.
